(19) United States
(12) Patent Application Publication
(10) Pub. No.: US 2010/0102850 A1
(43) Pub. Date: Apr. 29, 2010

(54) SEMICONDUCTOR DEVICE

(75) Inventor: Tadashi FUKUI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/604,910

(22) Filed: Oct. 23, 2009

(30) Foreign Application Priority Data
Oct. 24, 2008 (JP) 2008-274407

(51) Int. Cl. H03K 19/0175

(52) U.S. Cl. 326/80

(57) ABSTRACT

A semiconductor device includes an inductor configured to supply a current to a first node based on a higher voltage region power supply voltage. A first switch is configured to selectively supply a current from the first node into a third node based on a voltage on a second node; a second switch is configured to selectively supply a current from the first node into the second node based on a voltage of the third node; a third switch is configured to supply the current from the third node into a ground terminal based on a lower voltage region input logic level; and a fourth switch is configured to be turned ON/OFF alternately with the third switch to supply the current from the second node to the ground terminal.

### INCORPORATION BY REFERENCE

This patent application claims a priority on convention based on Japanese Patent Application No. 2008-274407. The disclosure thereof is incorporated herein by reference.

### BACKGROUND OF THE INVENTION

1. Field of the Invention

The present invention relates to a semiconductor device, and more particularly relates to a semiconductor device that includes a level converting circuit using two power supply groups which differ from each other

2. Description of Related Art

As a technique related to a conventional level converting circuit, Japanese Patent Application Publication (JP-A-Heisei, 5-284005: first conventional example) is known. In the conventional level converting circuit as shown in the first conventional example, an N-channel transistor is required to be operated at a low voltage. Thus, in order to increase the performance of a current at a low Vgs, the size of an N-channel MOS transistor (NMOS) is made as large as possible, and the size of a P-channel MOS transistor (PMOS) is required to be made as small as possible.

In this case, because of the lack of the performance of the P-channel transistor, especially as a voltage difference between a high voltage side and a low voltage side is greater, the switching time of the P-channel transistor becomes slower, which deteriorates a delay property.

Also, in order to improve the delay property, the transistor size is required to be made large, which results in the increase in a circuit size and the decrease in the improvement efficiency of the delay property that is caused by a parasitic capacitance of the transistor.

In the conventional level converting circuit, as the voltage difference between the high voltage side and the low voltage side is greater, the delay property of the level converting circuit is worse. In order to improve the delay property, the transistor size is required to be enlarged. However, as the transistor size is increased, the parasitic capacitance of the transistor size is increased, which decreases the improvement effect of the delay property. Thus, a technique is demanded for improving the delay property without enlarging the transistor size.

### SUMMARY OF THE INVENTION

In an aspect of the present invention, a semiconductor device includes an inductor configured to supply a current to a first node based on a higher voltage region power supply voltage. A first switch is configured to selectively supply a current from the first node into a third node based on a voltage on a second node; a second switch is configured to selectively supply a current from the first node into the second node based on a voltage of the third node; a third switch is configured to supply the current from the third node into a ground terminal based on a lower voltage region input logic level; and a fourth switch is configured to be turned ON/OFF alternately with the third switch to supply the current from the second node to the ground terminal.

The delay property of the level converting circuit of the semiconductor device of the present invention can be improved.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram showing a configuration of a level converting circuit as a semiconductor device according to a first embodiment of the present invention;

FIG. 2 is a circuit diagram showing a configuration of a conventional level converting circuit;

FIG. 3 is a graph diagram showing changes in voltages of respective nodes in the level converting circuits of the present invention and the conventional level converting circuit;

FIG. 4 is a circuit diagram showing a configuration of the level converting circuit according to a second embodiment of the present invention;

FIGS. 5A and 5B are circuit diagrams showing modifications of the level converting circuits according to the first and second embodiments of the present invention;

FIG. 6A is a circuit diagram showing a configuration of the level converting circuit according to a third embodiment of the present invention;

FIGS. 6B to 6D are circuit diagrams showing modifications of the level converting circuit according to the third embodiment of the present invention;

FIG. 7A is a circuit diagram showing a configuration of the level converting circuit according to a fourth embodiment of the present invention;

FIGS. 7B to 7D are circuit diagrams showing modifications of the level converting circuit according to the fourth embodiment of the present invention;

FIG. 8A is a circuit diagram showing a configuration of the level converting circuit according to a fifth embodiment of the present invention; and

FIGS. 8B to 8D are circuit diagrams showing modifications of the level converting circuit according to the fifth embodiment of the present invention.

### DESCRIPTION OF THE EMBODIMENTS

Hereinafter, a semiconductor device including a circuit such as a level converting circuit of the present invention will be described with reference to the attached drawings.

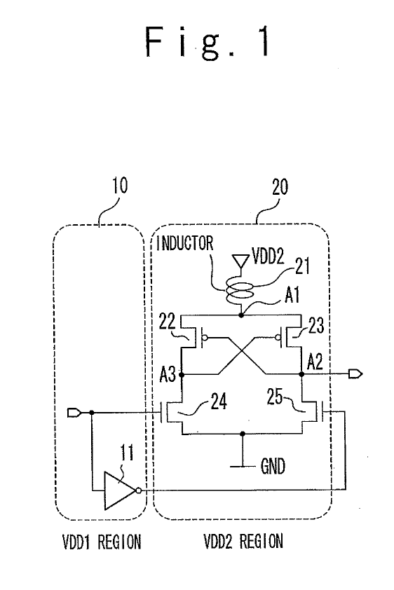

Referring to FIG. 1, the level converting circuit of the semiconductor device of the present invention includes a VDD1 region 10 and a VDD2 region 20. The VDD1 region 10 is a region for a circuit on the side of a low voltage operation, and the VDD2 region 20 is a region for a circuit on the side of a high voltage operation. Here, a power supply on the side of the VDD1 region 10 is defined as VDD1. Also, a power supply on the side of the VDD2 region 20 is defined as VDD2. In this case, the voltage of VDD2 is higher than the voltage of VDD1.

The VDD1 region 10 includes an inverter 11. The inverter 11 is a circuit that outputs a logic voltage level on an output side by inverting a logic voltage level of an input side. For example, the inverter 11 sets the voltage logic of the output side to a low level voltage (L) (Low), if the voltage of the input side is a high level voltage (H) (High). Oppositely, if the voltage logic of the input side is the low level voltage (L), the voltage of the output side is set to the high level voltage (H). Here, the inverter 11 receives a signal from an input terminal and inverts the voltage of the received signal and outputs it. That is, the inverter 11 inverts the voltage on the input terminal. It should be noted that the power supply on the input terminal and the power supply for driving the inverter 11 are the VDD1, although they are not shown.

The VDD2 region 20 includes an inductor 21, a first P-channel transistor 22, a second P-channel transistor 23, a first N-channel transistor 24 and a second N-channel transistor 25. Through the inductor 21, a current flows from a power supply terminal (VDD2) to a node A1 (first node). Here, the inductor 21 is provided between the power supply terminal (VDD2) and the node A1. When a resistance of the inductor is greater, its loss becomes greater. Thus, the resistance is preferred to be small. As the main structure of the inductor 21, there are a winding type, a lamination type, a thin film type and the like.

The first P-channel transistor 22 serves as a switch that is turned ON/OFF in accordance with the voltage on a node A2 (second node) and sends the current from the node A1 to a node A3 (third node). Here, in the first P-channel transistor 22, its gate is connected to the node A2, its source is connected to the node A1, and its drain is connected to the node A3. In FIG. 1, although the output terminal is connected to the node A2, there is a case that it is connected to the node A3. The second P-channel transistor 23 serves as a switch that is turned ON/OFF in accordance with the voltage of the node A3 and sends a current from the node A1 to the node A2. Here, in the second P-channel transistor 23, its gate is connected to the node A3, its source is connected to the node A1, and its drain is connected to the node A2.

The first N-channel transistor 24 serves as a switch that is turned ON/OFF in accordance with the voltage on an input side and sends s current from the node A3 to a ground terminal (GND). Here, in the first N-channel transistor 24, its gate is connected to an input terminal, its source is connected to the ground terminal (GND), and its drain is connected to the node A3. The second N-channel transistor 25 serves as a switch that is turned ON/OFF in accordance with the voltage on the output side in the inverter 11 and sends a current from the node A2 to the ground terminal (GND). That is, the second N-channel transistor 25 and the first N-channel transistor 24 are the switches that are alternately (complementarily) turned ON/OFF. Here, in the second N-channel transistor 25, its gate is connected to the output side in the inverter 11, its source is connected to the ground terminal (GND), and its drain is connected to the node A2.

In a state in which the voltage of the input terminal is “L”, the first P-channel transistor 22 and the second N-channel transistor 25 are ON, and the first N-channel transistor 24 and the second P-channel transistor 23 are OFF. When the voltage of the input terminal is switched from “L” to “H”, both of the second P-channel transistor 23 and the first N-channel transistor 24 are turned ON, and both of the first P-channel transistor 22 and the second N-channel transistor are turned OFF. When the voltage of the input terminal is switched from “H” to “L”, both of the first P-channel transistor 22 and the second N-channel transistor 25 are turned ON, and both of the second P-channel transistor 23 and the first N-channel transistor 24 are turned OFF.

The level converting circuit has a period during which at the time of the level conversion, the P-channel transistor and the N-channel transistor are turned ON at the same time, and a passing-through current flows between the power supply terminal (VDD2) and the ground terminal (GND). For example, when the first P-channel transistor 22 and the first N-channel transistor 24 (or, the second P-channel transistor 23 and the second N-channel transistor 25) are turned ON at the same time, the passing-through current flows between the power supply terminal (VDD2) and the ground terminal (GND). When this passing-through current flows through the inductor 21, the voltage of the node A1 is temporally decreased by an electromotive force induced in the inductor 21 and then increased. At this time, since Vgs (the gate voltage) of the P-channel transistor is enlarged, the current performance is increased. Thus, even if the transistor has a small size, the switching time of the level converting circuit can be made fast.

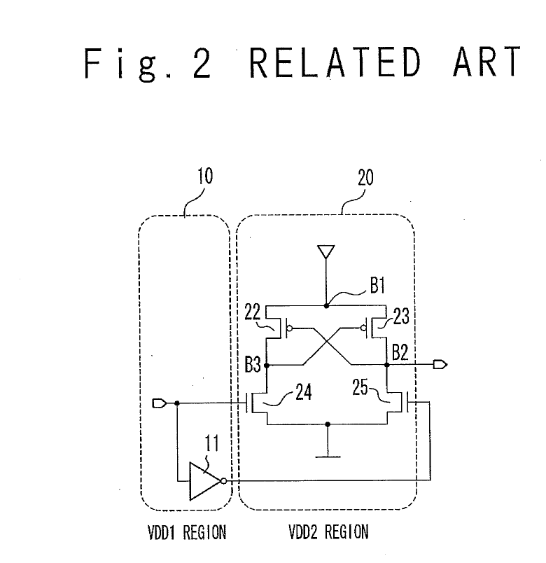

FIG. 2 shows a configuration example of a conventional level converting circuit, for comparison with the level converting circuit of the present invention. The conventional level converting circuit includes a VDD1 region 10 and a VDD2 region 20. The VDD1 region 10 includes an inverter 11. The VDD2 region 20 includes a first P-channel transistor 22, a second P-channel transistor 23, first N-channel transistor 24 and a second N-channel transistor 25. The inverter 11, the first P-channel transistor 22, the second P-channel transistor 23, the first N-channel transistor 24 and the second N-channel transistor 25 are basically same as those of the level converting circuit of the present invention.

The difference in configuration between the level converting circuits of the present invention and the conventional level converting circuit is in the presence or absence of the inductor 21. It should be noted that a node B1, a node B2 and a node B3 in the conventional level converting circuit correspond to the node A1, the node A2 and the node A3 in the level converting circuit of the present invention, respectively.

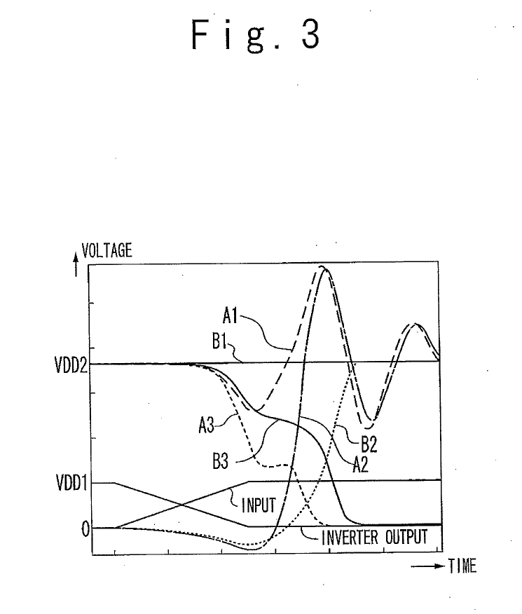

FIG. 3 is a diagram showing changes in voltage of the respective nodes in the level converting circuits of the present invention and the conventional level converting circuit. The “Input” waveform indicates the change in voltage of the input terminal. The “Inverter Output” waveform indicates the change in voltage of the output of the inverter 11. The “Node A1” waveform indicates the change in voltage of the node A1. The “Node A2” waveform indicates the change in voltage of the node A2. The “Node A3” waveform indicates the change in the voltage of the node A3. Here, for the convenience, the voltage of the power supply (VDD1) on the low voltage side is indicated as “VDD1”, and the voltage of the power supply (VDD2) on the high voltage side is indicated as “VDD2”.

These graphs show the changes in voltage of the respective nodes, when the voltage of the input terminal is changed from “L” to “H” (from 0 to VDD1). The voltage of the node A1 is varied upwardly and then downwardly by the electromotive force induced in the inductor 21, with respect to the power supply voltage (VDD2) on the high voltage side. On the other hand, the voltage of the node B1 is kept at the voltage of the power supply voltage (VDD2) and always constant.

When the voltage of the input terminal is changed from “L” to “H”, the voltages of the node A2 and the node B2 are also changed from “L” to “H”. At this time, the voltage of the node B1 is constant. Thus, even if the voltage of the node B2 is increased, it is increased only to the same voltage (VDD2) as the voltage of the node B1. However, since the voltage of the node A1 is varied, the voltage of the node A2 is increased to the peak (upper limit value) of the waveform of the node A1.

Also, the influence of the voltage increase in the node A causes the node A2 to be changed from “L” to “H” earlier than the node B2. The influence of the temporal voltage drop of the node A causes the node A3 to be changed from “H” to “L” earlier than the node B3. Consequently, the switching time can be made short. Also, the transistor size can be made small when the speed of the voltage drop in the node A3 is made approximately equal to the speed of the voltage drop in the node B3 (the same change time as the conventional technique).

It should be noted when the voltage of the input terminal is changed from “L” to “H”, the waveform of the node A3 becomes similar to the waveform of the node A2, and the waveform of the node A2 becomes similar to the waveform of the node A3. Specifically, the waveforms of the node A3 and the node A2 are replaced with each other.

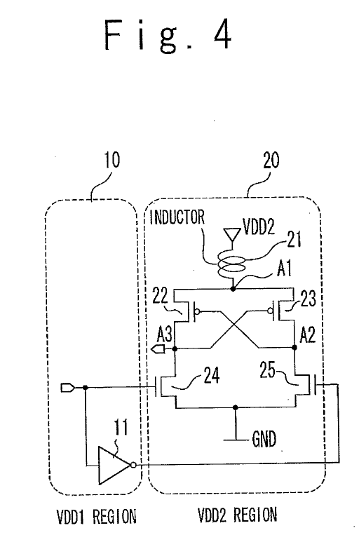

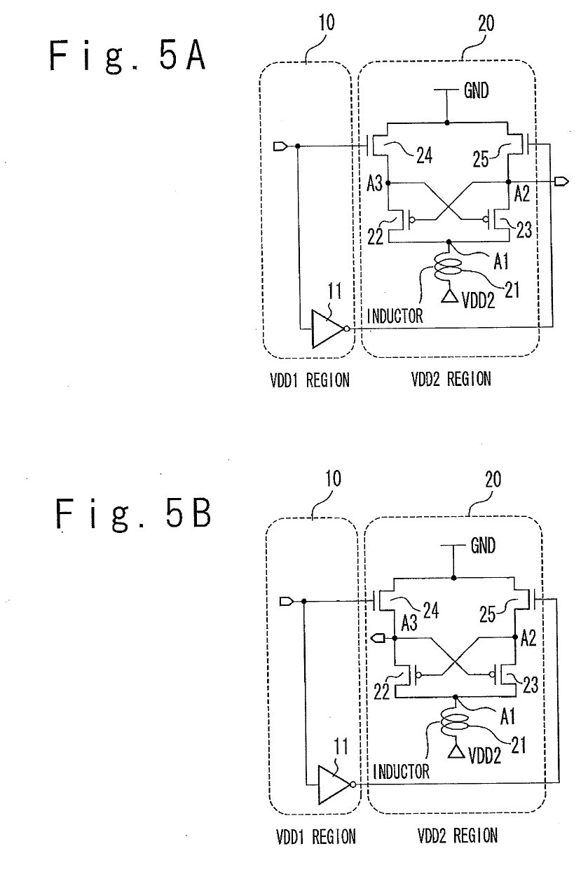

Next, the embodiments in which the present invention is applied to the configuration of the existing level converting circuit will be described below with reference to FIG. 4, FIGS. 5A and 5B, FIGS. 6A to 6D, FIGS. 7A to 7D and FIGS. 8A to 8D.

FIG. 4 is a circuit diagram showing a modification of the level converting circuit shown in FIG. 1. The level converting circuit shown in FIG. 4 includes the VDD1 region 10 and the VDD2 region 20. The VDD1 region 10 includes the inverter 11. The VDD2 region 20 includes the inductor 21, the first P-channel transistor 22, the second P-channel transistor 23, the first N-channel transistor 24 and the second N-channel transistor 25. The VDD1 region 10, the VDD2 region 20, the inverter 11, the inductor 21, the first P-channel transistor 22, the second P-channel transistor 23, the first N-channel transistor 24 and the second N-channel transistor 25 are basically same as those of the level converting circuit shown in FIG.

In the level converting circuit in FIG. 1, the node A2 is connected to the output terminal. However, in the level converting circuit in FIG. 4, the node A3 is connected to the output terminal.

FIG. 5A is a circuit diagram showing a modification in which the positions of the power supply terminal (VDD2) and the ground terminal (GND) are inverted, in the level converting circuit shown in FIG. 1. Also, FIG. 5B is a view showing the embodiment in which the positions of the power supply terminal (VDD2) and the ground terminal (GND) are inverted, in the level converting circuit shown in FIG. 4. Each of the level converting circuits shown in FIGS. 5A and 5B includes the VDD1 region 10 and the VDD2 region 20. The VDD1 region 10 includes the inverter 11. The VDD2 region 20 includes the inductor 21, the first P-channel transistor 22, the second P-channel transistor 23, the first N-channel transistor 24 and the second N-channel transistor 25. The VDD1 region 10, the VDD2 region 20, the inverter 11, the inductor 21, the first P-channel transistor 22, the second P-channel transistor 23, the first N-channel transistor 24 and the second N-channel transistor 25 are basically same as those of the level converting circuits shown in FIG. 1 or FIG. 4.

In the level converting circuit in FIG. 5A, the node A2 is connected to the output terminal. However, in the level converting circuit in FIG. 5B, the node A3 is connected to the output terminal.

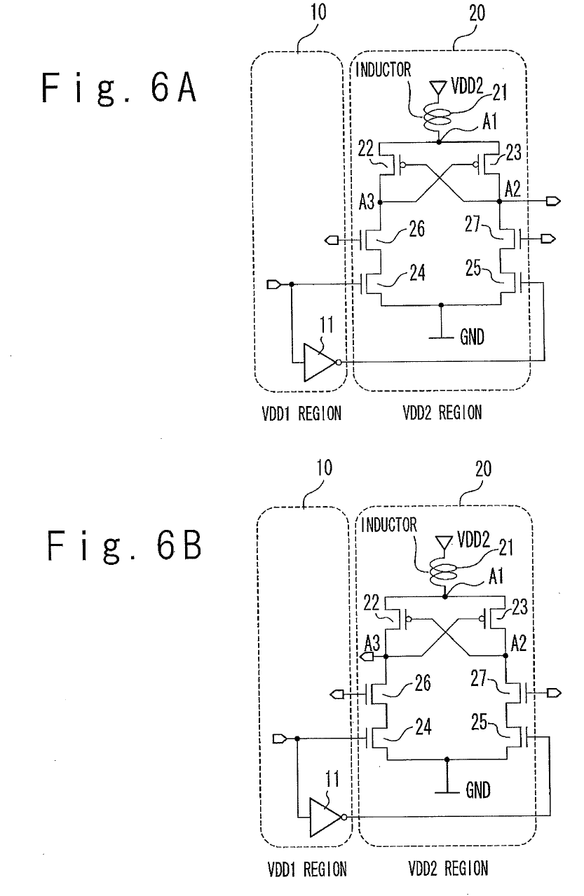

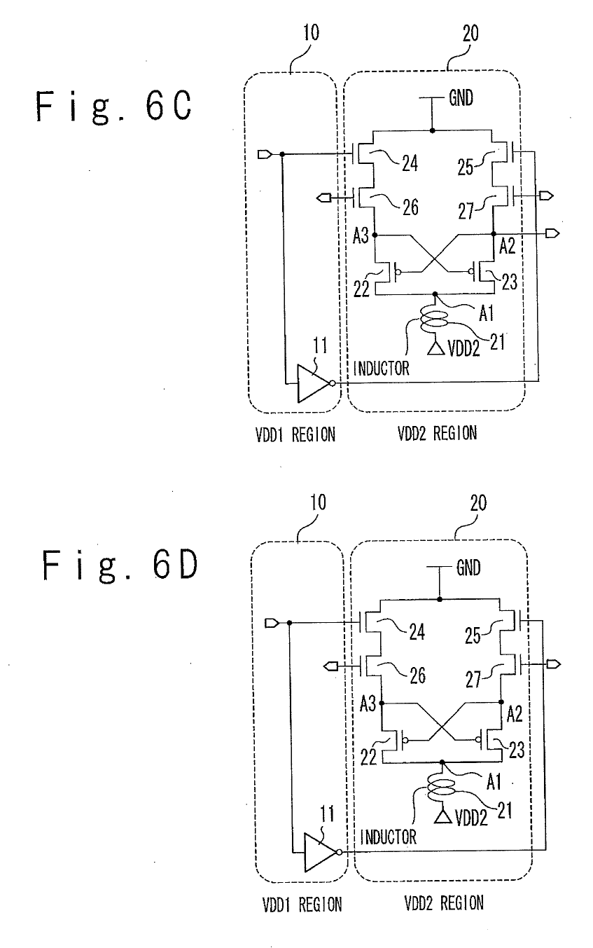

FIG. 6A is a circuit diagram showing a configuration of the level converting circuit in which N-channel transistors are further added to the level converting circuit shown in FIG. 1. Also, FIG. 6B is a circuit diagram showing a configuration of the level converting circuit in which N-channel transistors are further added to the level converting circuit shown in FIG. 4. Also, FIG. 6C is a circuit diagram showing a modification in which the positions of the power supply terminal (VDD2) and the ground terminal (GND) are inverted, in the level converting circuit shown in FIG. 6A. Also, FIG. 6D is a circuit diagram showing an example in which the positions of the power supply terminal (VDD2) and the ground terminal (GND) are inverted, in the level converting circuit shown in FIG. 6B.

Each of the level converting circuits shown in FIGS. 6A to 6D includes the VDD1 region 10 and the VDD2 region 20. The VDD1 region 10 includes the inverter 11. The VDD2 region 20 includes the inductor 21, the first P-channel transistor 22, the second P-channel transistor 23, the first N-channel transistor 24, the second N-channel transistor 25, a third N-channel transistor 26 and a fourth N-channel transistor 27. The VDD1 region 10, the VDD2 region 20, the inverter 11, the inductor 21, the first P-channel transistor 22, the second P-channel transistor 23, the first N-channel transistor 24 and the second N-channel transistor 25 are basically same as those of the level converting circuits shown in FIG. 1 and FIG. 4.

The third N-channel transistor 26 is provided between the node A3 and the first N-channel transistor 24. The third N-channel transistor 26 sends the current from the node A3 to the first N-channel transistor 24 in accordance with the voltage of the output terminal. Here, in the third N-channel transistor 26, its gate inputs the output of the output terminal, its source is connected to the drain side of the first N-channel transistor 24, and its drain is connected to the node A3. The voltage of the gate of the third N-channel transistor 26 is equal to the voltage of one of the node A2 or the node A3 which is connected to the output terminal.

The fourth N-channel transistor 27 is provided between the node A2 and the second N-channel transistor 25. The fourth N-channel transistor 27 sends the current from the node A2 to the second N-channel transistor 25 in accordance with the voltage of the output terminal. Here, in the fourth N-channel transistor 27, its gate inputs the output of the output terminal, its source is connected to the drain side of the second N-channel transistor 25, and its drain is connected to the node A2. The voltage of the gate of the fourth N-channel transistor 27 is equal to the voltage of one of the node A2 or the node A3 which is connected to the output terminal.

In the level converting circuits in FIG. 6A and FIG. 6C, the node A2 is connected to the output terminal. However, in the level converting circuits in FIG. 6B and FIG. 6D, the node A3 is connected to the output terminal.

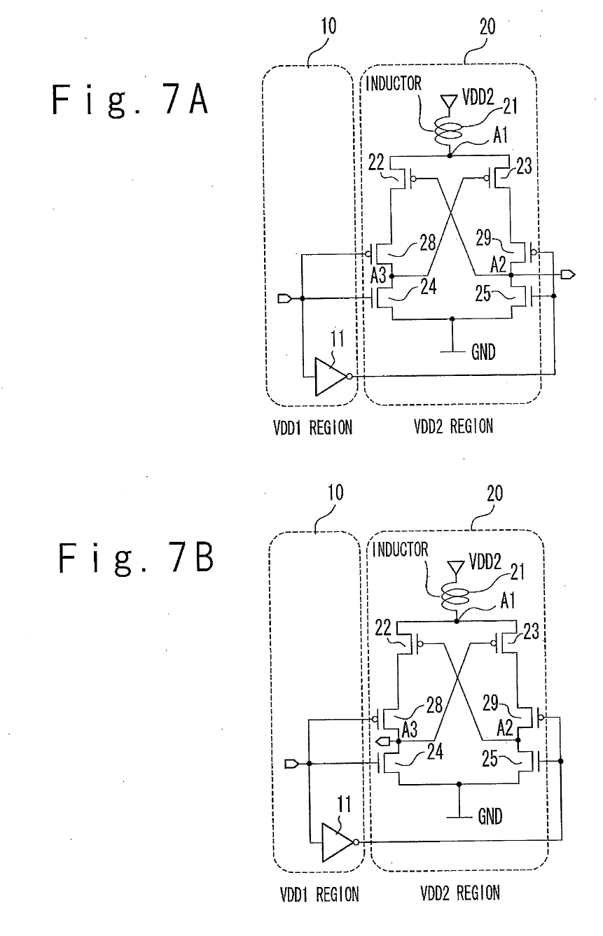

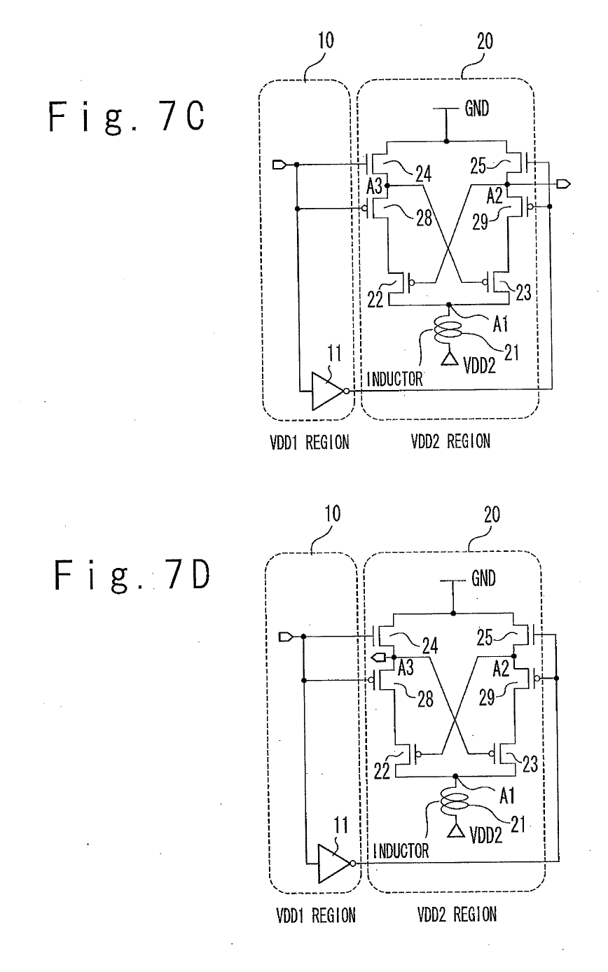

FIG. 7A is a circuit diagram showing a configuration of the level converting circuit in which the P-channel transistor is further added to the level converting circuit shown in FIG. 1. Also, FIG. 7B is a circuit diagram showing a configuration of the level converting circuit in which the P-channel transistor is further added to the level converting circuit shown in FIG. 4. Also, FIG. 7C is a circuit diagram showing an example in which the positions of the power supply terminal (VDD2) and the ground terminal (GND) are inverted, in the level converting circuit shown in FIG. 7A. Also, FIG. 7D is a circuit diagram showing an example in which the positions of the power supply terminal (VDD2) and the ground terminal (GND) are inverted, in the level converting circuit shown in FIG. 7B.

Each of the level converting circuits shown in FIGS. 7A to 7D includes the VDD1 region 10 and the VDD2 region 20. The VDD1 region 10 includes the inverter 11. The VDD2 region 20 includes the inductor 21, the first P-channel transistor 22, the second P-channel transistor 23, the first N-channel transistor 24, the second N-channel transistor 25, a third P-channel transistor 28 and a fourth P-channel transistor 29. The VDD1 region 10, the VDD2 region 20, the inverter 11, the inductor 21, the first P-channel transistor 22, the second P-channel transistor 23, the first N-channel transistor 24 and the second N-channel transistor 25 are basically equal to those of the level converting circuits shown in FIG. 1 and FIG. 4.

The third P-channel transistor 28 is provided between the first P-channel transistor 22 and the node A3. The third P-channel transistor 28 is the switch that is turned ON/OFF in accordance with the voltage of the input terminal and sends the current from the first P-channel transistor 22 to the node A3. Here, in the third P-channel transistor 28, its gate is connected to the input terminal, its source is connected to the drain side of the first P-channel transistor 22, and its drain is connected to the node A3. The fourth P-channel transistor 29 is provided between the second P-channel transistor 23 and the node A2. The fourth P-channel transistor 29 is the switch that is turned ON/OFF in accordance with the voltage of the output side in the inverter 11 and sends the current from the second P-channel transistor 23 to the node A2. Here, in fourth P-channel transistor 29, its gate is connected to the output side in the inverter 11, its source is connected to the drain side of the second P-channel transistor 23, and its drain is connected to the node A2.

In the level converting circuits in FIG. 7A and FIG. 7C, the node A2 is connected to the output terminal. However, in the level converting circuits in FIG. 7B and FIG. 7D, the node A3 is connected to the output terminal.

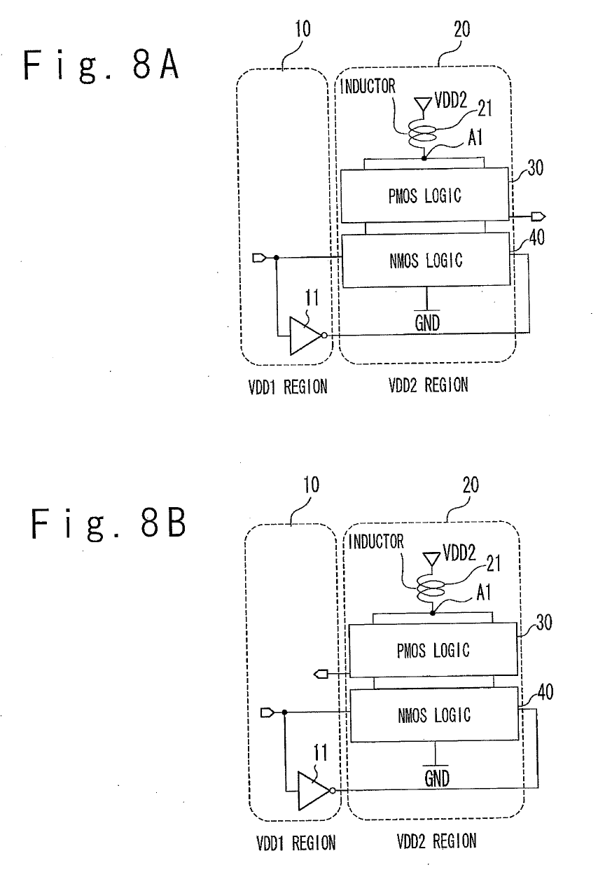

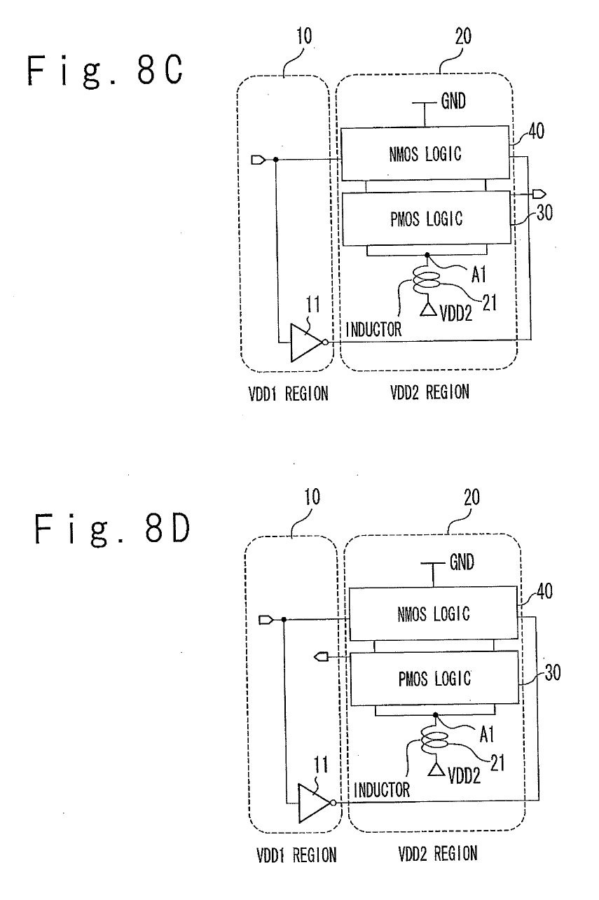

FIG. 8A is a block diagram showing an embodiment in which in the level converting circuit shown in FIG. 1, the zones corresponding to the P-channel transistor and the N-channel transistor are changed to a PMOS logic and an NMOS logic, respectively. Also, FIG. 8B is a block diagram showing an embodiment in which in the level converting circuit shown in FIG. 4, the zones corresponding to the P-channel transistor and the N-channel transistor are changed to the PMOS logic and the NMOS logic, respectively. Also, FIG. 8C is a block diagram showing an embodiment in which in the level converting circuit shown in FIG. 8A, the positions of the power supply terminal (VDD2) and the ground terminal (GND) are inverted. Also, FIG. 8D is a block diagram showing an embodiment in which in the level converting circuit shown in FIG. 8B, the positions of the power supply terminal (VDD2) and the ground terminal (GND) are inverted.

Each of the level converting circuits shown in FIGS. 8A to 8D includes the VDD1 region 10 and the VDD2 region 20. The VDD1 region 10 includes the inverter 11. The VDD2 region 20 includes the inductor 21, a PMOS logic circuit 30 and an NMOS logic circuit 40. The VDD1 region 10, the VDD2 region 20 and the inverter 11 are basically equal to those of the level converting circuits shown in FIGS. 1 and 4.

The PMOS logic circuit 30 is not a circuit that is provided with the first P-channel transistor 22 and the second P-channel transistor 23, as shown in FIGS. 1 and 4. However, this is a circuit having the same function as the circuit that is provided with the first P-channel transistor 22 and the second P-channel transistor 23. That is, the PMOS logic circuit 30 is the circuit serving as “Variation” of the circuit that is provided with the first P-channel transistor 22 and the second P-channel transistor 23. The NMOS logic circuit 40 is not a circuit that is provided with the first N-channel transistor 24 and the second N-channel transistor 25, as shown in FIGS. 1 and 4. However, this is a circuit having the same function as the circuit that is provided with the first N-channel transistor 24 and the second N-channel transistor 25. That is, the NMOS logic 40 is the circuit serving as “Variation” of the circuit that is provided with the first N-channel transistor 24 and the second N-channel transistor 25.

Here, the nodes A2 and A3 are, assumed to be included in the PMOS logic 30. However, actually, the nodes A2 and A3 may not be included in the PMOS logic 30. In the level converting circuits in FIGS. 8A and 8C, the zone corresponding to the node A2 in FIG. 1 is connected to the output terminal. However, in the level converting circuits in FIGS. 8B and 8D, the zone corresponding to the node A3 in FIG. 4 is connected to the output terminal.

It should be noted that the voltage of the output terminal is not limited to constraints such as the low voltage side and the high voltage side. That is, tentatively, even if the output terminal is indicated on the low voltage side in the drawing, the voltage of the output terminal has no relation to the voltage (VDD1) of the power supply on the low voltage side.

As mentioned above, the present invention has one feature that in the level converting circuit, in order to improve the delay property, the inductor is provided on the high voltage side. Usually, the inductor is not used in the level converting circuit. Usually, the use of the inductor is intentionally avoided because noise is generated by the induced electromotive force. The present invention positively uses the noise caused by the induced electromotive force in the inductor, and varies the voltage of the power supply voltage that is supplied to the high voltage side inside the level converting circuit. Then, the change in the voltage of the predetermined node inside the level converting circuit is accelerated or amplified in accordance with the increase or decrease in the voltage of the power supply voltage.

Specifically, in the present invention, the inductor is provided on the high voltage side in the level converting circuit. The induced electromotive force is generated in the inductor by the current generated when the level converting circuit is switched. Then, the voltage of the node A1 (the connection point between the level converting circuit and the inductor) in the level converting circuit is tentatively decreased by the induced electromotive force in the inductor 21 and then increased. At time of the temporal decrease in the voltage of the node A1, the speed of the decrease in the voltage of the node A3 is made fast. Also, at time of the increase in the voltage of the node A1, the speed of the increase in the voltage of the node A2 is made fast, and there is a case that the voltage of the node A2 is higher than the power supply voltage. Consequently, it is possible to improve the delay property of the level converting circuit and miniaturize the circuit size.

That is, in the present invention, it is possible to improve the delay property of the level converting circuit, by using only the inductor, without increasing the performance of the transistor (the transistor size), while keeping the configuration of the conventional level converting circuit.

It is also easy to subsequently mount the inductor described in the present invention into the conventional level converting circuit. Thus, the present invention can be applied to the existing level converting circuit. Thus, the present invention can be applied to the existing electronic apparatus that uses the level converting circuit. Also, it is adequate to only perform an, inductor adding process on the final step of the existing manufacturing line. Hence, it is not necessary to largely change the existing manufacturing line.

As the examples of the semiconductor device having the level converting circuit of the present invention, IC (Integrated Circuit), LSI (Large Scale Integration), a microprocessor, a computer, a mobile terminal, a digital camera, a display, an acoustic equipment, home electronics, a car and the like are considered. However, actually, it is not limited to those examples.

As mentioned above, the embodiments of the present invention have been detailed. However, actually, they are not limited to the above-mentioned embodiments. Even the change in the range without departing from the scope and spirit of the present invention is included in the present invention.

What is claimed is:

1. A semiconductor device comprising:
an inductor configured to supply a current to a first node based on a higher voltage region power supply voltage;
a first switch configured to selectively supply a current from said first node into a third node based on a voltage on a second node;
a second switch configured to selectively supply a current from said first node into said second node based on a voltage of said third node;
a third switch configured to supply the current from said third node into a ground terminal based on a lower voltage region input logic level; and
a fourth switch configured to be turned ON/OFF alternately with said third switch to supply the current from said second node to said ground terminal.

2. The semiconductor device according to claim 1, wherein the voltage of said first node varies due to electromotive force induced said inductor to increase or decrease with respect to the higher voltage side power supply voltage,
when the lower voltage region input logic level varies from a low logic level to a high logic level, the voltage of said second node varies from a low logic level to a high logic level due to the increase of the first node voltage faster than a case of no inductor so as to become higher than the higher voltage side power supply voltage, and
when the lower voltage region input logic level varies from the low logic level to the high logic level, the voltage of said third node decreases from the high logic level to the low logic level due to the decrease of the first node voltage faster than a case of no inductor so as to become lower than the higher voltage side power supply voltage.

3. The semiconductor device according to claim 1, wherein either of said second node and said third node is connected with an output terminal.

4. The semiconductor device according to claim 3, wherein said first switch is a first P-channel transistor, said second switch is a second P-channel transistor, said third switch is a first N-channel transistor, and said fourth switch is a second N-channel transistor.

5. The semiconductor device according to claim 4, further comprising:
a third N-channel transistor provided between said third node and said first N-channel transistor to supply a current from said third node to said first N-channel transistor based on the voltage of said output terminal; and
a fourth N-channel transistor provided between said second node and said second N-channel transistor to supply a current from said second node to said second N-channel transistor based on the voltage of said output terminal.

6. The semiconductor device according to claim 4, further comprising:
a third P-channel transistor provided between said third node and said first P-channel transistor to supply a current from said first P-channel transistor to said third node based on the lower voltage region input logic level; and
a fourth P-channel transistor provided between said second node and said second P-channel transistor to supply a current from said second P-channel transistor to said second node based on the lower voltage region input logic level.

7. The semiconductor device according to claim 1, wherein said first switch and said second switch are a part of a P-channel MOS logic circuit, and
said third switch and said fourth switch are a part of an N-channel MOS logic circuit.
